(19) United States
(12) Patent Application Publication
(10) Pub. No.: US 2008/0142956 A1
(43) Pub. Date: Jun. 19, 2008

(54) Stress management in BGA packaging

(76) Inventors: Bertrand F. Cambou, Palo Alto, CA (US); Melissa Grupen-Shemansky, Los Gatos, CA (US); Lam Tim Fai, Suzhou (CN)

Correspondence Address: Paul J. Winters, 307 Cypress Point Drive, Mountain View, CA, 94043, US

(21) Appl. No.: 11/641,506

(22) Filed: Dec. 19, 2006

(51) Int. Cl. H01L 23/34

(52) U.S. Cl. 257/723

(57) ABSTRACT

The present semiconductor structure includes a substrate having a planar surface, a semiconductor chip attached to the planar surface of the substrate, the chip preferably being of the same thickness as or thinner than the substrate, and a package body attached to the substrate and to the semiconductor chip. The semiconductor chip and substrate are sufficiently rigidly attached so that substantial force applied parallel to the planar surface of the substrate may be transmitted therebetween, reducing temperature-change stress on solder balls which connect the substrate with a PCB. The semiconductor chip with advantage is thinned to reduce the stress on the solder balls.

### BACKGROUND OF THE INVENTION

1. Technical Field

This invention relates generally to Ball Grid Array (BGA) semiconductor devices for mounting on for example a Printed Circuit Board (PCB), and more particularly, to management of stresses thereof.

2. Background Art

Shown in FIG. 1 is a semiconductor device 20. This semiconductor device 20 is of a ball grid array (BGA) configuration which will now be described. As shown in FIG. 1, a carrier substrate 22, planar in configuration, has a planar chip attach surface 24. A silicon chip 26 is attached to the surface 24 of the substrate 22 by a chip bond 28. A plurality of solder balls 30 are attached to the substrate 22 on the side thereof opposite the chip 26. The semiconductor chip 26 is electrically connected to the plurality of solder balls 30 by wires 32 connecting the chip 26 to traces and vias 34 through the substrate 32, which vias 34 connect to the solder balls 30. A molded package body 36 is formed over the resulting structure as shown, enclosing the chip 26 and wires 32. The solder balls 30 extending from the substrate 22 are attached to a Printed Circuit Board (PCB) 38.

The material of the substrate 22 (for example BT resin) and the material of the PCB 38 are selected so that they have similar Coefficients of Thermal Expansion (CTE). This is done in an attempt to reduce stress on the balls 30 interconnecting the substrate 22 and PCB 38 as the device 20 and PCB 38 expand and contract due to changes in temperature.

The CTE of the substrate 22 (and of the PCB 38) is substantially higher than the CTE of the silicon chip 26. For example, the CTE of the silicon chip 26 may be on the order of 2.7-3.5 ppm/° C., while the CTE of the substrate 22 may be on the order of 14-15 ppm/° C. (similar to the CTE of the PCB 38). With the silicon chip 26 attached to the substrate 22, the small CTE of the chip 26 relative to that of the substrate 22 will have an effect on the overall CTE of the chip-substrate combination, since the chip 26 expands at a lower rate than the substrate 22 for a given increase in temperature. That is, for example, assuming that the solder balls 30 are substantially unstressed with the device 20 and PCB 38 at room temperature, as temperature increases, the silicon chip 26 will to an extent hold back the expansion of the substrate 22 in all directions parallel to the planar surface 24 of the substrate 22, as compared to what would be expected if the substrate 22 were free from the chip 26. This causes a degree of stress in the solder balls 30 connecting the substrate 22 and PCB 38 (which is not constrained in expansion as is the substrate 22). Without the silicon chip 26 present, the substrate 22 will expand and contract much like the PCB 38 resulting in little or no stress on the solder balls.

With the silicon chip 26 of relatively small size as compared to the substrate 22 (see FIGS. 1 and 2), the effect of the silicon chip 26 on the substrate 22 is relatively small, and with the CTE's of the substrate 22 and PCB 38 being similar, with such temperature increase, undue stress is not placed on the solder balls 30 connecting the substrate 22 and PCB 38.

Recently, there has been an effort to decrease the size of such a semiconductor device. Toward this end, for example, the substrate has been decreased in area relative to the chip, resulting in a substrate 22A and silicon chip 26 being much closer in overall area (FIG. 4). With the chip 26 attached to the substrate 22A as described above, the small CTE of the chip 26 relative to that of the substrate 22A has a substantially greater effect on the overall CTE of the chip-substrate combination than as previously described. This is so because the size of the chip 26 relative to the size of the substrate 22A is much greater than as previously described. Thus, the silicon chip 26 will to a greater extent hold back the expansion of the substrate 22A relative to the PCB 38, causing greatly increased stress on the solder balls 30 connecting the substrate 22A and PCB 38.

An attempt to deal with this problem is illustrated in FIG. 3. This semiconductor device 20A is again of a ball grid array (BGA) configuration. Again, the carrier substrate 22A, planar in configuration, has a planar chip attach surface 24A. The silicon chip 26 is attached to the surface 24A of the substrate 22A by a resilient, compliant layer 40 having a relatively low modulus of elasticity. The plurality of solder balls 30 are attached to the substrate 22A on the side thereof opposite the chip 26. The semiconductor chip 26 is electrically connected to the plurality of solder balls 30 by wires 32 connecting the chip 26 to traces and vias 34 through the substrate 22A, which vias 34 connect to the solder balls 30. The solder balls 30 extending from the substrate 22A are attached to a Printed Circuit Board (PCB) 38. During changes in temperature, through the “de-coupling” of the silicon chip 26 and the substrate 22A by means of the compliant layer 40, the compliant layer 40 allows relatively free movement between the substrate 22A and silicon chip 26 in directions parallel and/or perpendicular to the planar surface 24A of the substrate 22A, avoiding the constraining effects of the chip 26 on the substrate 22A as described above. This allows the substrate 22A and PCB 38 to expand and contract at substantially the same rate for a given change in temperature, avoiding substantial stress on the solder balls 30.

While these approaches are relatively effective in their environment, it is desirable to minimize stresses on the solder balls due to temperature change where the area of the silicon chip is relatively large as compared to the area of the substrate, and wherein molding compound is used to encapsulate the silicon chip and protect the chip and interconnects from the atmosphere, which can have a corrosive effect on those materials and contribute to other reliability failures in the field. Molding compound provides protection against the corrosive effect of the atmosphere and any contaminants, but also to make the package mechanically robust (does not “give” under force like a rubber material) so it may be handled without damage and attached to the PCB without warping. Inherently, the molding compound “couples” the die to the substrate

Therefore, what is needed is an approach for minimizing temperature induced stress on the solder balls in such an environment.

### DISCLOSURE OF THE INVENTION

Broadly stated, the present semiconductor structure comprises a substrate having a planar surface, a semiconductor chip attached to the planar surface of the substrate, the chip preferably being of the same thickness as or thinner than the substrate, and a package body attached to the substrate and to the semiconductor chip, the semiconductor chip and substrate being sufficiently rigidly attached so that substantial force applied parallel to the planar surface of the substrate may be transmitted therebetween.

The present invention is better understood upon consideration of the detailed description below, in conjunction with the accompanying drawings. As will become readily apparent to those skilled in the art from the following description, there are shown and described embodiments of this invention simply by way of the illustration of the best mode to carry out the invention. As will be realized, the invention is capable of other embodiments and its several details are capable of modifications and various obvious aspects, all without departing from the scope of the invention. Accordingly, the drawings and detailed description will be regarded as illustrative in nature and not as restrictive.

### BRIEF DESCRIPTION OF THE DRAWINGS

The novel features believed characteristic of the invention are set forth in the appended claims. The invention itself, however, as well as said preferred mode of use, and further objects and advantages thereof, will best be understood by reference to the following detailed description of illustrative embodiments when read in conjunction with the accompanying drawings, wherein:

FIG. 1 is a cross-sectional view of a first semiconductor device in accordance with the above description;

FIG. 2 is a plan view of a portion of the device of FIG. 1;

FIG. 3 is a cross-sectional view of a second semiconductor device in accordance with the above description;

FIG. 4 is a plan view of a portion of the device of FIG. 3;

FIGS. 5-14 are views illustrating various approaches in managing stresses in mounted BGA devices; and

FIGS. 15-17 illustrate systems incorporating devices of the present invention.

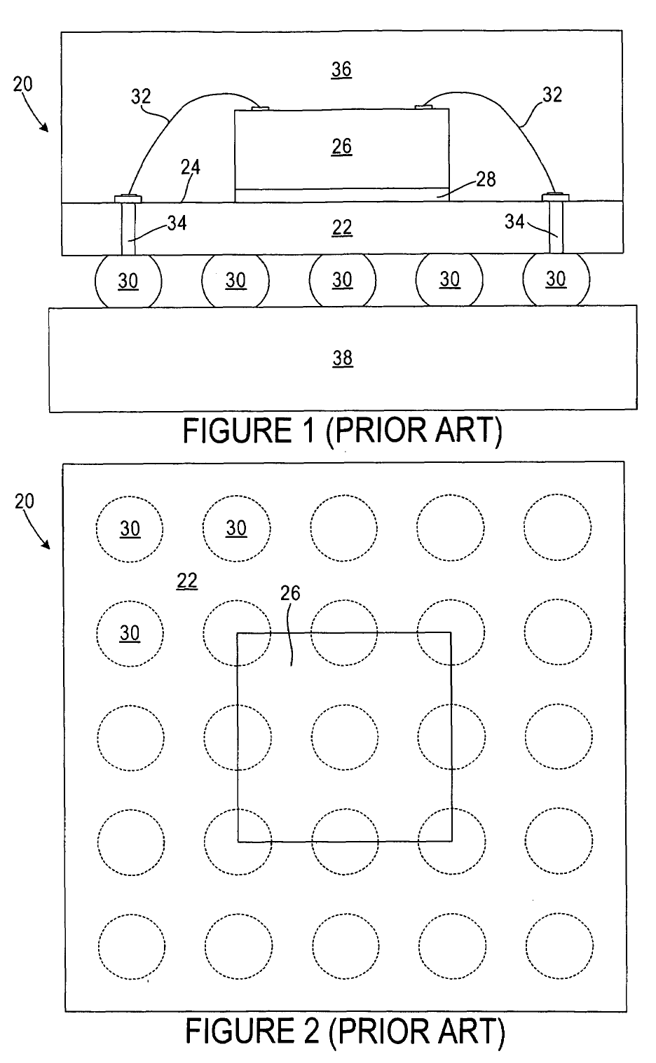

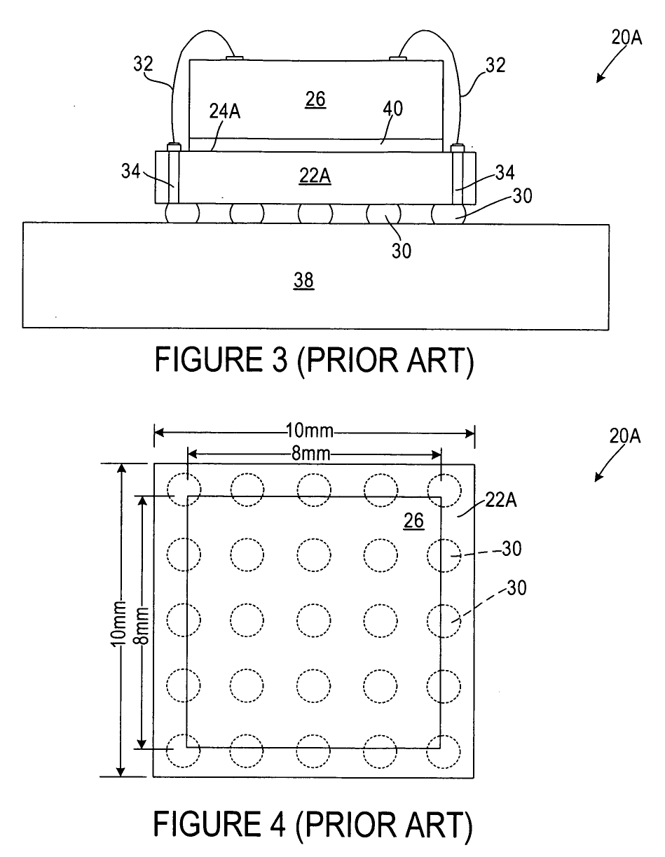

### BEST MODE(S) FOR CARRYING OUT THE INVENTION

Reference is now made in detail to specific embodiments of the present invention which illustrate the best mode presently contemplated by the inventors for practicing the invention.

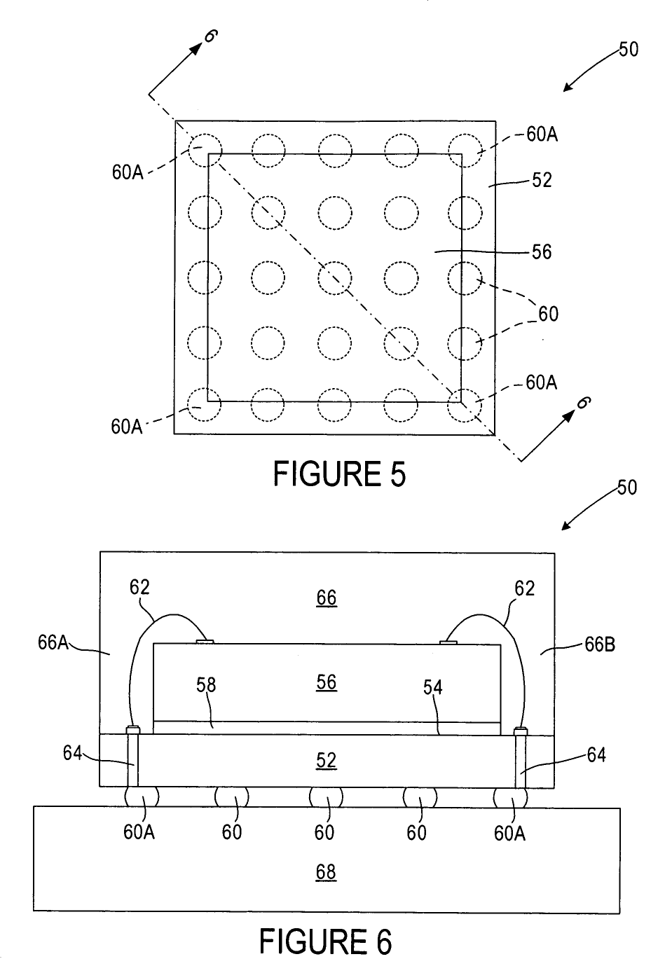

FIGS. 5 and 6 illustrate a first approach in dealing with the problems set forth above. Shown in FIG. 6 is a semiconductor device 50. This semiconductor device 50 is of a ball grid array (BGA) configuration. A carrier substrate 52, planar in configuration, has a planar chip attach surface 54. A silicon chip 56 is attached to the surface 54 of the substrate 52 by, in this embodiment, a resilient, compliant layer 58 having a relatively low modulus of elasticity (for example Hitachi Cable's elastomer or polyimide tab tape). A plurality of solder balls 60 are attached to the substrate 52 on the side thereof opposite the chip 56 (while 25 solder balls are shown, it will be understood that the number is actually much greater, i.e. several hundred). The semiconductor chip 56 is electrically connected to the plurality of solder balls 60 by wires 62 connecting the chip 56 to vias 64 through the substrate 52, which vias 64 connect to the solder balls 60. A rigid plastic molded package body 66 is formed over the resulting structure as shown, enclosing the chip 56 and wires 62 and attaching strongly to the substrate 52 and the silicon chip 56 so as to provide a sturdy overall device. The solder balls 60 extending from the substrate 52 are attached to a Printed Circuit Board (PCB) 68.

The material of the substrate 52 (for example BT resin or polyimide), the material of the PCB 68 (for example FR4), and the material of the package body 66 (for example mold compound plastic) are selected so that they have similar Coefficients of Thermal Expansion (CTE). The properties of the various materials are:
For BT resin substrate: CTE=14-15 ppm/° C.
   Modulus of Elasticity E @ 25° C.=˜20 GPa
For polyimide substrate: CTE=9-11 ppm/° C.
   Modulus of Elasticity E @ 25° C.=2-7 GPa
For FR4 PCB: CTE=15-20 ppm/° C.
   Modulus of Elasticity E @ 25° C.=˜17 GPa
For mold compound plastic package: CTE=13-20 ppm/° C.
   Modulus of Elasticity E @ 25° C.=2-20 GPa
For silicon chip: CTE=2.5-3.7 ppm/° C.

As will be seen, the CTE of the substrate 52 is substantially higher than the CTE of the silicon chip 56.

The solder balls are SnPb alloys ranging from 37% Pb to 97% Pb or Pb-free alloy such as SnAgCu alloys of various concentrations.

The dimensions of the chip 56 are 8 mm×8 mm, while the dimensions of the substrate 52 are 10 mm×10 mm, so that the chip 56 area is more than 60% of the area of the substrate 52 (in this embodiment 64%, See FIG. 5).

FIG. 5 illustrates a portion of the device 50 in plan view, indicating the section 6-6 (FIG. 6) across which maximum expansion and contraction occurs for a given change in temperature. For a difference in expansion and contraction between the PCB 68 and substrate 52, the maximum difference in movement (and maximum stress) will be placed on the outermost, i.e. outer corner solder balls 60A of the device 50, since that is where the difference in expansion and contraction between the PCB 68 and substrate 52 is at a maximum.

The low E of the layer 58 attaching the chip 56 to the substrate 52 allows for relatively free movement of one relative to the other in directions parallel to the planar surface 54 of the substrate 52. However, as pointed out above, the plastic package body 66 is strongly attached to the silicon chip 56 and to the substrate 52. With an increase in temperature, and with the strong attachment of the plastic package body 66 to the substrate 52 and silicon chip 56, the walls 66A, 66B of the plastic package body 66 attached to the silicon chip 56 are held from freely expanding in directions parallel to the planar surface 54 of the substrate 52. That is, while the silicon chip 56 is resiliently mounted to the substrate 52, transferring minimal force thereto in directions parallel to the planar surface 54 of the substrate 52, substantial force is applied from the silicon chip 56 to the sidewalls 66A, 66B of the plastic package body 66 and to the substrate 52 where the plastic package body 66 attaches to the substrate 52. This substantial force limits expansion of the substrate 52 relative to the PCB 68, causing substantial stress to be placed on the solder balls 60, with maximum stress concentrated over and being placed on the outermost (corner) balls 60A where maximum difference in movement occurs.

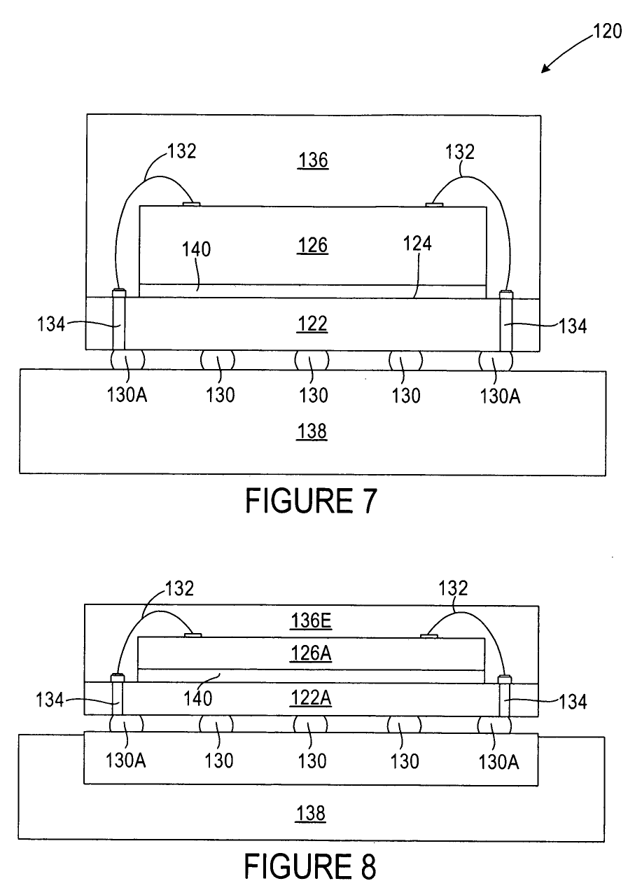

FIG. 7 illustrates a second approach in dealing with the problems set forth above. Shown in FIG. 7 is a semiconductor device 120 including a carrier substrate 122, planar in configuration, having a planar chip attach surface 124. A silicon chip 126 is attached to the surface 124 of the substrate 122. A plurality of solder balls 130 are attached to the substrate 122 on the side thereof opposite the chip 126. The semiconductor chip 126 is electrically connected to the plurality of solder balls 130 by wires 132 connecting the chip 126 to vias 134 through the substrate 122, which vias 134 connect to the solder balls 130. A rigid plastic molded package body 136 is formed over the resulting structure as shown, enclosing the chip 126 and wires 132 and attaching strongly to the substrate 122 and the silicon chip 126 so as to provide a sturdy overall device 120. The solder balls 130 extending from the substrate 122 are attached to a PCB 138. The specifications, including dimensions, of these components are as set forth above with regard to FIGS. 5 and 6.

Again, the CTE of the silicon chip 126 is substantially lower than the CTE of the substrate 122 (and of the PCB 138), and the chip 126 is of large area compared to the area of the substrate 122, as above. However, instead of providing an attaching layer of low E between the semiconductor chip 126 and the substrate 122, an attaching layer 140 of high E, approximately 1.0 GPa or more @ 25° C., for example, Hitachi HS-230 (E=1.0 GPa at 25° C., CTE alpha1=115 ppm/° C., CTE alpha2=260 ppm/° C.) is used for attaching the semiconductor chip 126 to the substrate 122. As another example, Hysol QMI 546 (E=1.0 GPa at 25° C., CTE=80 ppm/° C.) may be provided as the attaching layer 140. This attaching layer 140 is capable of transmitting substantial force applied parallel to the planar surface 124 of the substrate 122. That is, for example, if a force is applied to one of the semiconductor chip 126 and substrate 122 in a direction parallel to the planar surface 124 of the substrate 122, a substantial portion of that force will be transmitted to the other of the semiconductor chip 126 and substrate 122 through the high E attaching layer 140. This transmittal of force more evenly distributes force across the interface of the semiconductor chip and the plastic package body 136 with the substrate 122, avoiding the concentration of force where the plastic package body 136 attaches to the substrate 122 as describe above, in turn avoiding applying maximum force over the outermost solder balls 130A, reducing relative movement between the substrate 122 and PCB 138, particularly in the areas of the of outermost solder balls 130A. This reduction in movement reduces stress on the solder balls 130, particularly the outermost solder balls 130A, which are most susceptible to failure with changes in temperature. As a comparison, using an attaching layer with a relatively low E, for example Hitachi Cable elastomer (E=0.55 GPa at 25° C., CTE=86 ppm/° C.) as the attaching layer leads to the problems set forth above, resulting in undesirably high stress placed on the solder balls.

The device 120B of FIG. 8 illustrates a substantially thinned silicon chip 126A (for example with thickness equal to the thickness of the substrate 122A). The thinning of the chip relative to the substrate reduces the size of the silicon chip 126A relative to the substrate 122A and the package body 138E (which has itself been reduced in size as compared to previous embodiments), reducing the effect of the lower CTE of the silicon chip 126A thereon so as to alleviate stress on the solder balls 130. In addition, the thinning of the chip 126A causes it to become more elastic in nature, i.e., less brittle and less prone to fracture under stress, for example stress caused by temperature change.

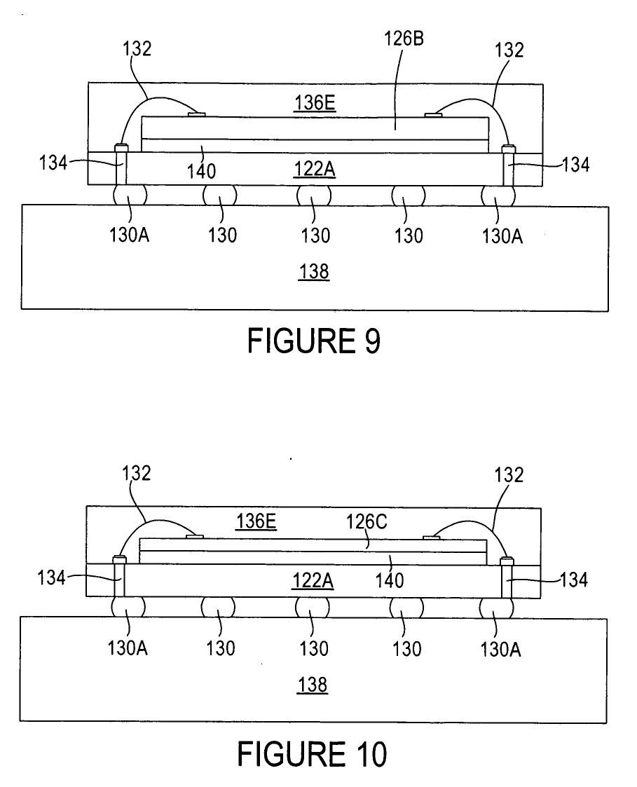

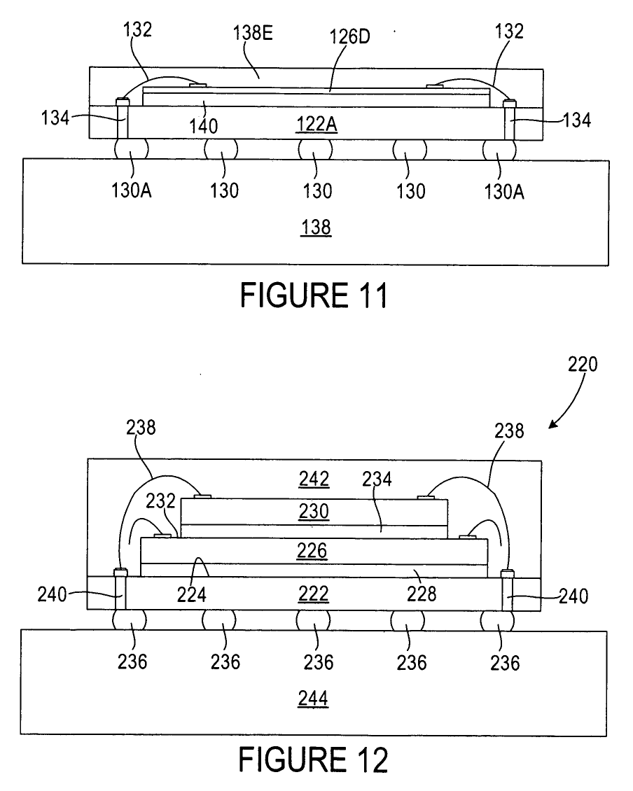

This advantage is increased with further reduction of the thickness of the chip relative to the substrate, i.e., chip 126B thickness less than thickness of substrate 122A (chip 126B thickness being and shown as less than 75% thickness of substrate 122A (FIG. 9), chip 126C thickness being and shown as less than 50% thickness of substrate 122A (FIG. 10), chip 126D thickness being and shown as less than 25% thickness of substrate 122A (FIG. 11). Each of these reductions provides further significant advantage in decreasing the size of the chip relative to the substrate 122A and the package body 138E, incrementally reducing the effect of the lower CTE of the silicon chip thereon so as to alleviate stress on the solder balls 130. In addition, each thinning of the chip causes it to become more elastic in nature, i.e., less brittle and less prone to fracture under stress.

FIG. 12 illustrates a first embodiment of multi-chip device 220 in accordance with the present invention. Similar to the previous embodiment, the device 220 includes including a carrier substrate 222, planar in configuration, having a planar chip attach surface 224. A silicon chip 226 is attached to the surface 224 of the substrate 222 by means of an attaching layer 228 of high E, E being approximately 1.0 GPa or more @ 25° C., for example, Hitachi HS-230 (E=1.0 GPa at 25° C., CTE alpha1=115 ppm/° C., CTE alpha2=260 ppm/° C.). As another example, Hysol QMI 546 (E=1.0 GPa at 25° C., CTE=80 ppm/° C.) may be provided as the attaching layer 140. A second silicon chip 230 is attached to the upper surface 232 of the silicon chip 226, the attaching layer 234 also of a high E, the specifications thereof being as those of the attaching layer 228. A plurality of solder balls 236 are attached to the substrate 222 on the side thereof opposite the chips 226, 230. The semiconductor chips 226, 230 are electrically connected to the plurality of solder balls 236 by wires 238 connecting the chips 226, 230 to vias 240 through the substrate 222, which vias 240 connect to the solder balls 236. A rigid plastic molded package body 242 is formed over the resulting structure as shown, enclosing the chips 226, 230 and wires 238 and attaching strongly to the substrate 222 and the silicon chips 226, 230. The solder balls 236 extending from the substrate are 222 are attached to a PCB 242. The specifications of these components are as set forth above. All other specifications being the same as previously shown and described, the CTE of the silicon chips 226, 230 will have more of an effect with changes in temperature than in the single-chip embodiment. However, the attaching layers 228, 234 of high E are capable of transmitting forces as described above sufficiently to provide a high level of protection from stresses to the solder balls 236.

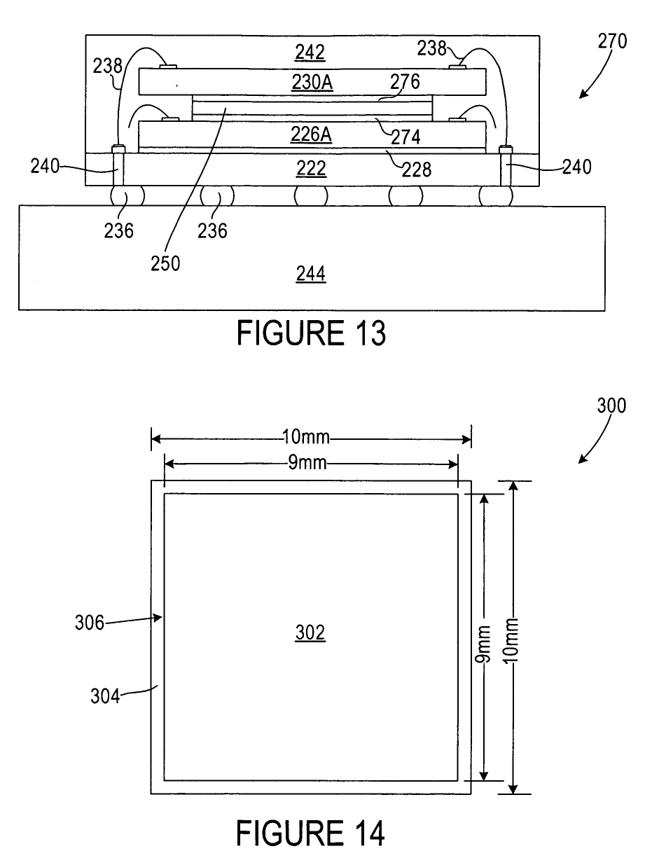

FIG. 13 illustrates a second embodiment of multi-chip device 270 in accordance with the present invention. The specifications of this embodiment are as set forth with regard to FIG. 10. However, in this embodiment, the chips 226A, 230A are separated by a spacer 272 which is attached to both the chip 226A and the chip 230A by means of high E attaching layers 274, 276 as specified above. The above advantages apply in this multi-chip environment also.

FIG. 14 illustrates a single-chip device 300 where the dimensions the of the chip 302 are 9 mm×9 mm, while the dimensions of the substrate 304 are 10 mm×10 mm, so that the chip 302 area is more than 80% of the area of the substrate 304 (in this embodiment 81%, see FIG. 12). This provides a chip scale device, defined as one wherein the substrate is 0-20% larger in area than the area of the chip. With all other dimensions and specifications being the same as previously shown and described, the CTE of the silicon chip 302, being of larger area relative to the area of the substrate 304, will have more of an effect with changes in temperature than in the embodiment of FIG. 7. However, the attaching layer 306 attaching the chip 302 and the substrate 304, being of high E as in the embodiment of FIG. 7, is capable of transmitting forces as described above sufficiently to provide a high level of protection from stresses to the solder balls.

It will be seen that in the present approach, where the area of the silicon chip or chips is relatively large as compared to the area of the substrate, and wherein molding compound is used to encapsulate the silicon chip or chips, stresses on the solder balls due to temperature change are substantially reduced as compared to other approaches.

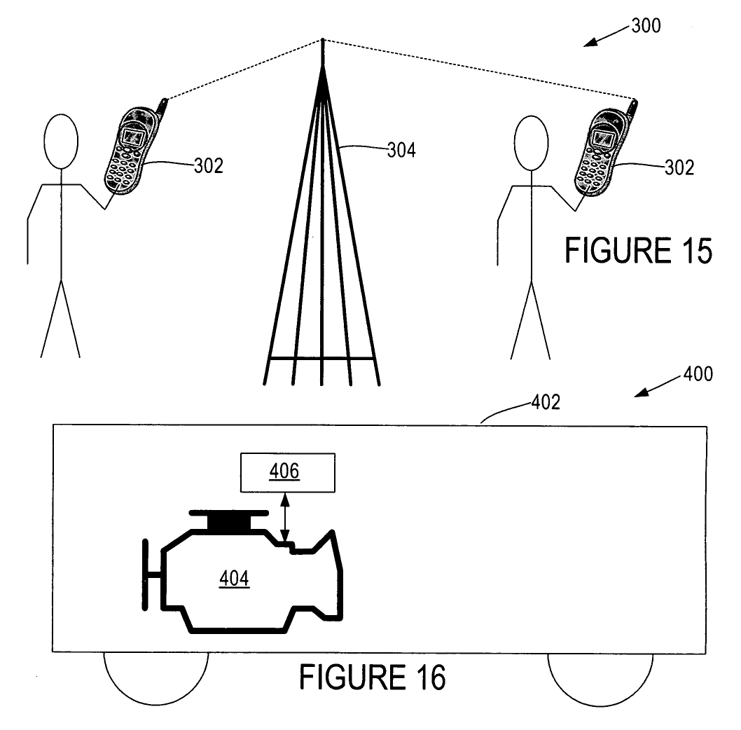

FIG. 15 illustrates a system 300 utilizing memory devices as described above. As shown therein, the system 300 includes hand-held devices in the form of cell phones 302, which communicate through an intermediate apparatus such as a tower 304 (shown) and/or a satellite. Signals are provided from one cell phone to the other through the tower 304. Such a cell phone 302 with advantage uses memory devices of the type described above for data storage, for example names, telephone number and other data. One skilled in the art will readily understand the advantage of using such memory devices in other hand-held devices which utilize data storage, such as portable media players, personal digital assistants, digital cameras and the like.

FIG. 16 illustrates another system 400 utilizing memory devices as described above. The system 400 includes a vehicle 402 having an engine 404 controlled by an electronic control unit 406. The electronic control unit 406 with advantage uses memory devices of the type described above for data storage, for example data relating to engine and vehicle operating conditions.

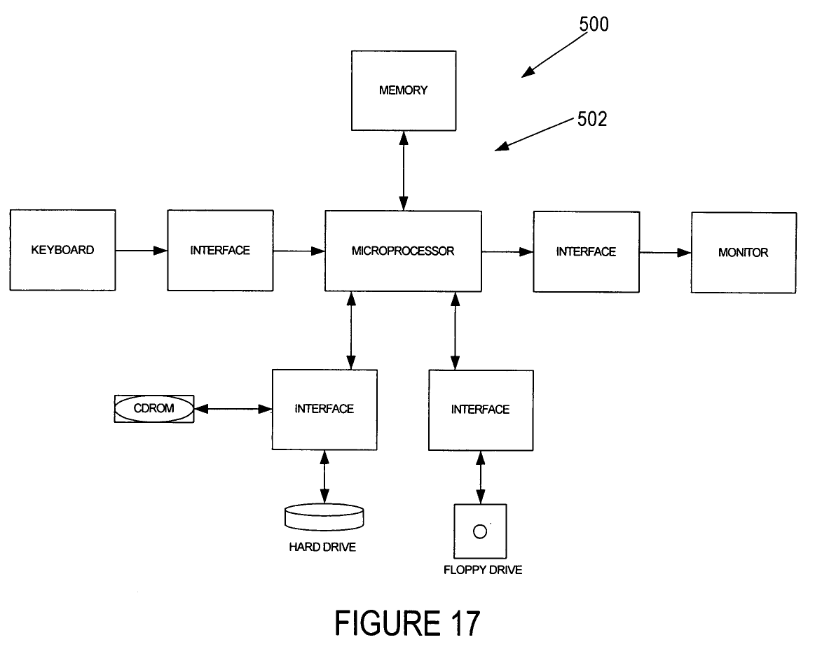

FIG. 17 illustrates yet another system 500 utilizing memory devices as described above. This system 500 is a computer 502 which includes an input in the form of a keyboard, and a microprocessor for receiving signals from the keyboard through an interface. The microprocessor also communicates with a CDROM drive, a hard drive, and a floppy drive through interfaces. Output from the microprocessor is provided to a monitor through an interface. Also connected to and communicating with the microprocessor is memory which may take the form of ROM, RAM, flash and/or other forms of memory. The memory with advantage uses memory devices of the type described above for storage of any data which is of use.

The foregoing description of embodiments of the invention has been presented for purposes of illustration and description. It is not intended to be exhaustive or to limit the invention to the precise form disclosed. Other modifications or variations are possible in light of the above teachings.

The embodiments were chosen and described to provide the best illustration of the principles of the invention and its practical application to thereby enable one of ordinary skill of the art to utilize the invention in various embodiments and with various modifications as are suited to the particular use contemplated. All such modifications and variations are within the scope of the invention as determined by the appended claims when interpreted in accordance with the breadth to which they are fairly, legally and equitably entitled.

What is claimed is:

1. A semiconductor structure comprising:
a substrate having a planar surface;
a semiconductor chip attached to the planar surface of the substrate;
a package body attached to the substrate and to the semiconductor chip;
the semiconductor chip and substrate being sufficiently rigidly attached so that substantial force applied parallel to the planar surface of the substrate may be transmitted therebetween.

2. The semiconductor structure of claim 1 wherein the semiconductor chip and substrate have substantially different coefficients of thermal expansion.

3. The semiconductor structure of claim 2 wherein the substrate has a substantially higher coefficient of thermal expansion than the coefficient of thermal expansion of the semiconductor chip.

4. The semiconductor structure of claim 1 wherein the area of the semiconductor chip is more than 60% of the area of the substrate.

5. The semiconductor structure of claim 1 wherein the area of the semiconductor chip is more than 80% of the area of the substrate.

6. The semiconductor structure of claim 1 wherein the coefficient of thermal expansion of the package body is similar to the coefficient of thermal expansion of the substrate.

7. The semiconductor structure of claim 6 wherein the substrate has a substantially higher coefficient of thermal expansion than the coefficient of thermal expansion of the semiconductor chip.

8. The semiconductor structure of claim 1 and further comprising an attachment layer for attaching the semiconductor chip and the substrate, the attachment layer having a modulus of elasticity of approximately 1.0 GPa or more.

9. The semiconductor structure of claim 1 wherein the thickness of the semiconductor chip is equal to or less than the thickness of the substrate.

10. The semiconductor structure of claim 1 and further comprising a plurality of conductors attached to the substrate, and a board, the conductors attached to the substrate being attached to the board.

11. The semiconductor structure of claim 10 wherein the conductors are solder balls.

12. The semiconductor structure of claim 11 wherein the substrate has a substantially higher coefficient of thermal expansion than the coefficient of thermal expansion of the semiconductor chip.

13. The semiconductor structure of claim 12 wherein the coefficient of thermal expansion of the board is similar to the coefficient of thermal expansion of the substrate.

14. A semiconductor structure comprising:
a substrate;
a semiconductor chip attached to the substrate;
a package body attached to the substrate and to the semiconductor chip;
wherein the thickness of the semiconductor chip is equal to or less than the substrate.

15. The structure of claim 14 wherein the thickness of the semiconductor chip is less than 75% of the thickness of the substrate.

16. The structure of claim 14 wherein the thickness of the semiconductor chip is less than 50% of the thickness of the substrate.

17. The structure of claim 14 wherein the thickness of the semiconductor chip is less than 25% of the thickness of the substrate.

18. The semiconductor structure of claim 14 wherein the area of the semiconductor chip is more than 60% of the area of the substrate.

19. The semiconductor structure of claim 14 wherein the area of the semiconductor chip is more than 80% of the area of the substrate.

20. A semiconductor structure comprising:
a substrate having a planar surface;
a first semiconductor chip attached to the planar surface of the substrate;
a second semiconductor chip attached to the first semiconductor chip;
a package body attached to the substrate and to the first and second semiconductor chips;
the first semiconductor chip and substrate being sufficiently rigidly attached so that substantial force applied parallel to the planar surface of the substrate may be transmitted therebetween.

21. The semiconductor structure of claim 20 wherein the first and second semiconductor chips have similar coefficients of thermal expansion, and the substrate has a coefficient of thermal expansion substantially different from that of the first semiconductor chip.

22. The semiconductor of structure of claim 21 and further comprising a plurality of conductors attached to the substrate, and a board, the conductors attached to the substrate being attached to the board.

23. The semiconductor structure of claim 22 wherein the conductors are solder balls.

24. The semiconductor structure of claim 23 and further comprising an attachment layer for attaching the first semiconductor chip and the substrate, the attachment layer having a modulus of elasticity of approximately 1.0 GPa or more.

25. A semiconductor structure comprising:
a substrate having a planar surface;
a first semiconductor chip attached to the planar surface of the substrate;
a spacer attached to the first semiconductor chip;
a second semiconductor chip attached to the spacer;
a package body attached to the substrate and to the first and second semiconductor chips;
the first semiconductor chip and substrate being sufficiently rigidly attached so that substantial force applied parallel to the planar surface of the substrate may be transmitted therebetween.

26. The semiconductor structure of claim 25 wherein the first and second semiconductor chips have similar coefficients of thermal expansion, and the substrate has a coefficient of thermal expansion substantially different from that of the first semiconductor chip.

27. The semiconductor of structure of claim 26 and further comprising a plurality of conductors attached to the substrate, and a board, the conductors attached to the substrate being attached to the board.

28. The semiconductor structure of claim 27 wherein the conductors are solder balls.

29. The semiconductor structure of claim 28 and further comprising an attachment layer for attaching the first semiconductor chip and the substrate, the attachment layer having a modulus of elasticity of approximately 1.0 GPa or more.

30. The method of claim 1 and further comprising said semiconductor structure incorporated in a system.

31. The method of claim 30 wherein the system is selected from the group consisting of a hand-held device, a vehicle, and a computer.
